(19) United States
(12) Patent Application Publication
(10) Pub. No.: US 2004/0162707 A1
(43) Pub. Date: Aug. 19, 2004

(54) Early alert and response system

(76) Inventors: Paula J. Saint-Amour, West Hurley, NY (US); Peter A. Schleim, West Hurley, NY (US)

Correspondence Address: TUCKER, ELLIS & WEST LLP, 1150 HUNTINGTON BUILDING, 925 EUCLID AVENUE, CLEVELAND, OH, 44115-1475, US

(21) Appl. No.: 10/777,330

(22) Filed: Feb. 12, 2004

Related U.S. Application Data
(60) Provisional application No. 60/447,031, filed on Feb. 12, 2003.

(51) Int. Cl. H03F 1/26

(52) U.S. Cl. 702/189

(57) ABSTRACT

An early alert and response system and method for identifying a public health risk stemming from an introduction of a chemical and/or biological contaminant. The system is a real-time attendance tracking software system that monitors attendance information for students. The attendance information is monitored to identify trends that may be indicative of a public health risk. The present invention is also directed to an electronic bus routing system that enables parents of students to monitor bus routes assigned to their students and change the bus routes as necessary.

### CROSS-REFERENCE TO RELATED APPLICATIONS

The present application claims the benefit of U.S. Provisional Application 60/447,031, filed Feb. 12, 2003.

### BACKGROUND OF THE INVENTION

This invention is directed to an Early Alert and Response System (EARS™) for identifying a public health risk stemming from any deliberate or accidental introduction of chemical or biological agent contaminants. More particular, this invention is an Early Alert and Response System which provides direction for emergency response planning and which is easy-to-use and implement for wide-spread application.

The Sep. 11, 2001 terrorist attacks on the U.S. have focused attention on the need to harness science and technology for homeland security and counter-terrorism purposes. Currently there are many new initiatives to identify and assess vulnerabilities. Several initiatives have been proposed and many are currently being developed and deployed. For example, one such initiative involves securing the infrastructure, and tightening physical security and airport security. Another initiative involves employing real-time sensor monitors, to monitor boundaries, water, air-quality, etc. Finally, another initiative involves bio-surveillance, gathering and monitoring health information data. For this bio-surveillance initiative, the government and independent labs are developing real time sensor based monitoring systems and technologies to protect vulnerable infrastructures from chemical or biological attacks.

The government is also currently funding a variety of initiatives to develop early warning health surveillance systems based on information technologies. Congress has allocated funds to various institutions, including the Centers for Disease Control & Prevention, for developing such a monitoring system, and state health departments have received grants to develop databases for capturing and tracking public-health indicator data.

However, while many initiatives are under way to develop early warning health surveillance systems, and significant progress is being made, advanced sensor technologies with wide scale deployment is years away. We cannot wait. America is a large, open and porous country. Even if a fully developed system were available, it will be doubtful that it would be economically feasible to deploy and equip every city and zip code in the United States with a network of sensors. And even if economically feasible and fully developed and deployed, it is highly unlikely that they will have a 100% success rate to detect all airborne and/or waterborne attacks. A terrorist attack could be carried out in a manner that leaves the county unaware of the event itself. Identification occurs days or even weeks later—when significant numbers of people become ill. At that point it may be too late to respond effectively. To ensure an effective response it is essential to combat any major public-health threat at the earliest possible moment.

Early detection has been the key to success in the war on cancer. It will be the key to success in the event of a bio-terrorism event or a pandemic. Today we do not have an early warning system for the early detection of an emerging public health emergency. The current detection model is based on “the astute clinician.” We rely on early and accurate diagnosis of unusual aberrant patterns of disease/health problems. We cross our fingers and hope that health and medical professionals will identify an emerging health threat and notify the appropriate Department of Health authorities.

The present invention is a system for early detection that when retrospectively analyzed on previous health emergencies (waterborne outbreaks of Salmonella and E. coli contamination) was significantly more adept at identifying the emerging health treat than the “astute Clinicians” did at the time. The present invention would have altered health authorities 3-4 weeks earlier. If the system had been in place at the time lives would have been saved and thousands of people could have avoided life-threatening illnesses.

There is a need for a system which would serve as a possible predictor of any emerging public health risk and that can be implemented quickly and efficiently.

### SUMMARY OF THE INVENTION

In accordance with the present invention, there is provided an easy-to-use early alert and response system for identifying any public health risk stemming from any deliberate or accidental introduction of chemical or biological agent contaminants, by aggregating current existing disparate data to help identify emerging public-health trends.

Further, in accordance with the present invention, there is provided an early alert and response system which provides direction for emergency response planning and which is easy-to-use and implement for wide spread application.

In the present invention, school attendance is tracked for more than ninety two million children in the nation's school systems by real-time attendance tracking software systems. This attendance data is then aggregated into on-line attendance tracking models, and then analyzed for emerging public-health trends.

According to one aspect, the present invention is directed to an electronic system for identifying a public health risk. The system includes attendance input means adapted for periodically receiving data representative of attendance information for at least one selected student; associating means adapted for associating the input attendance information with demographic information of the at least one selected student to form associated attendance information; analyzing means adapted for analyzing the associated attendance information against data representative of selected criteria to identify a public health risk; and means for outputting data representative of an identified public heath risk.

According to another aspect, the present invention is directed to a method for identifying a public health risk. The method includes the steps periodically receiving input data representative of attendance information for at least one selected student; associating the input attendance information with demographic information of the at least one selected student to form associated attendance information; analyzing the associated attendance information against data representative of selected criteria to identify a public health risk; and outputting data representative of an identified public heath risk.

According to yet another aspect, the present invention is directed to an electronic school bus routing system. The system includes assigned bus route displaying means adapted for displaying assigned bus route information for at least one selected student; alternate bus route displaying means adapted for displaying at least one alternate bus route information for the at least one selected student; and selection means adapted for receiving user input representative of a selection of an alternate bus route for the at least one selected student.

These and other advantages, aspects, and features will be understood by one of ordinary skill in the art upon reading and understanding the specification.

### BRIEF DESCRIPTION OF THE DRAWINGS

FIG. 1 is a flow chart illustrating the early alert and response system of the present invention;

FIG. 2 is a diagram illustrating the Opening Menu Screen for the Desktop application of the early alert and response system of the present invention;

FIG. 3 is a diagram illustrating the Manage/Take Class Attendance Screen for the Desk-top application of the early alert and response system of the present invention;

FIG. 4 is a diagram illustrating the Upload Class Attendance Screen for the Desktop application of the early alert and response system of the present invention;

FIG. 5 is a diagram illustrating the Manage Student Information Screen for the Desktop application of the early alert and response system of the present invention;

FIG. 6 is a diagram illustrating the Manage and Set-up Class Information Screen for the Desktop application of the early alert and response system of the present invention;

FIG. 7 is a diagram illustrating the Set-up and Edit Student Information Screen for the Desktop application of the early alert and response system of the present invention;

FIG. 8 is a diagram illustrating the Manage/Take Class Attendance Screen for the Active, Palm type hand-held device application of the early alert and response system of the present invention;

FIG. 9 is a diagram illustrating the Password Sign-on Screen for the Web-based on-line application of the early alert and response system of the present invention;

FIG. 10 is a diagram illustrating the Update Absenteeism Option Screen for the Web-based on-line application of the early alert and response system of the present invention;

FIG. 11 is a diagram illustrating Select a Student Information Screen for the Web-based on-line application of the early alert and response system of the present invention;

FIG. 12 is a diagram illustrating Change/Edit Student Information Screen for the Web-based on-line application of the early alert and response system of the present invention; and

FIG. 13 is a diagram illustrating an Email Screen for the Web-based on-line application of the early alert and response system of the present invention.

### DETAILED DESCRIPTION OF THE PREFERRED EMBODIMENT

The present invention is directed to an early alert and response system for identifying a public health risk stemming from any purposeful, deliberate or accidental introduction of chemical or biological agent contaminants. The invention is described in detail with its preferred embodiment which is in connection with monitoring of students. However, it is to be appreciated that the subject invention is also advantageously employed in any other social or group based activity, such as pre-schools, camps, retreats, sporting camps, and the like. The subject invention is accomplished by aggregating current existing disparate attendance data from elementary schools, to help identify emerging public-health trends. Thus, by monitoring our children's school attendance, the system can effectively create an early warning barometer to signal whether a public-health risk is developing within the United States. More importantly, this system can be ready for wide-scale deployment in a relatively short time.

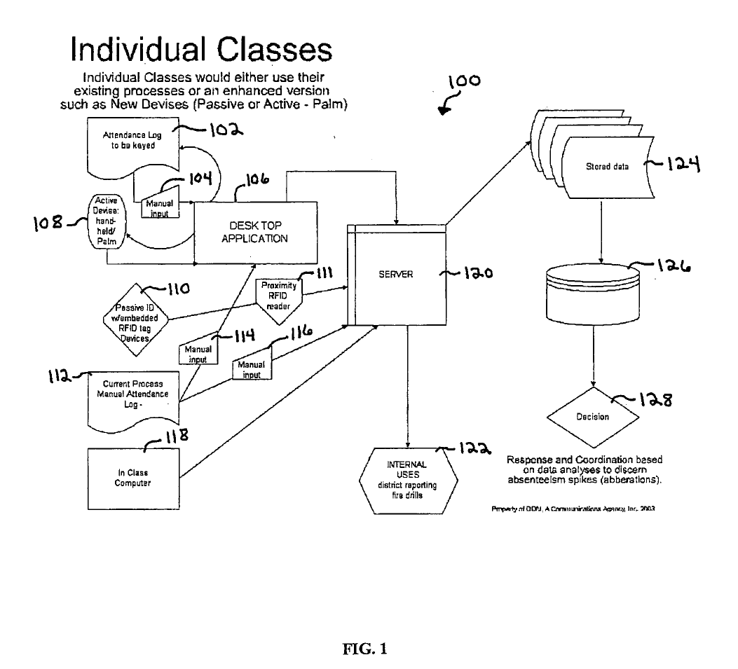

A diagram illustrating the early alert and response system 100 is shown in FIG. 1. In the present invention, several process methodologies for the collection of attendance in classes and the subsequent on-line aggregation of that attendance data into attendance tracking models have been structured ranging from high-tech to low-tech. For example, attendance data can be entered directly via a desktop application 102, active devices, such as a Palm type hand-held device 108, passive ID devices 110, a paper-based method 112, an RFID reader, or an on-line web based application 118.

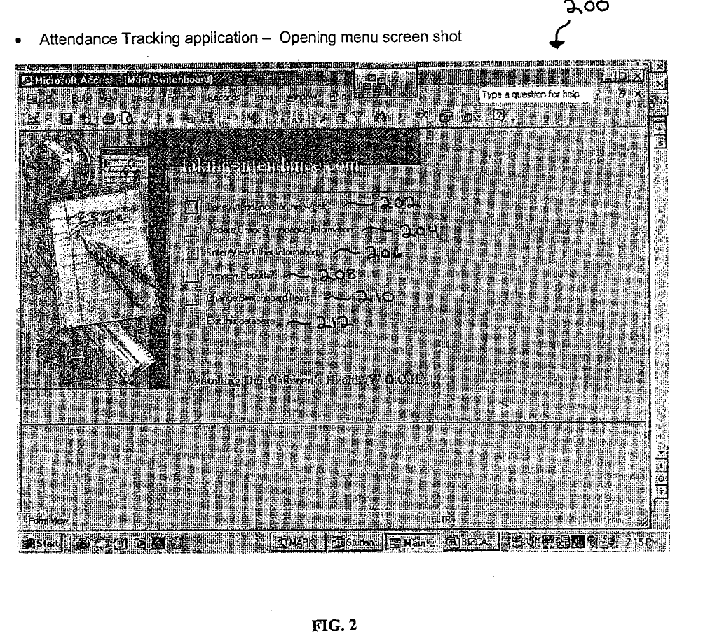

The desktop application 102 allows a user to enter attendance data directly into a desktop, and then update this data directly to the server. The attendance log is keyed in manually 104 and then uploaded to a proprietary desk-top application 106, which is then updated directly to the web server 120. For example, a user logs into the menu screen 200, as shown in FIG. 2, then selects a specific method of inputting or viewing data by clicking on the specific category. A user can choose to take attendance for a specific week 202, update online attendance information 204, enter/view other attendance information 208, change switchboard items 210, or exit this database 212.

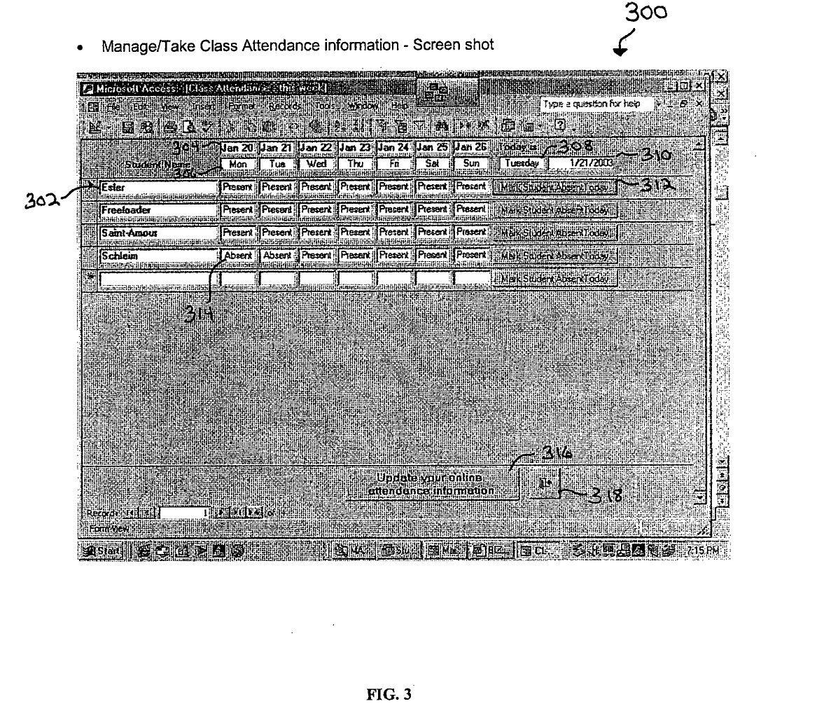

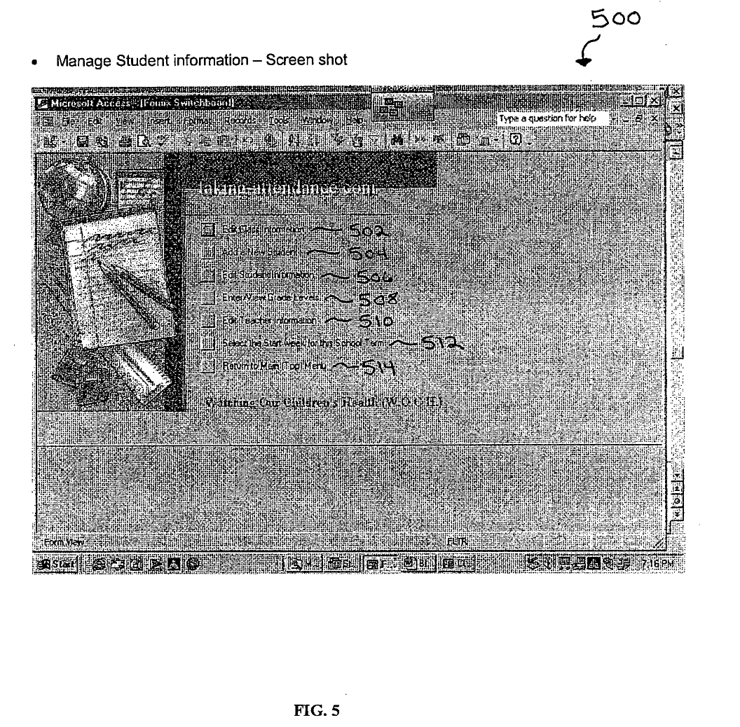

If a user chooses to take attendance for the week 202, they are transferred to the manage/take class attendance screen 300, as shown in FIG. 3. The attendance screen 300 displays the selected student's name 302, the date 310, day of the week 308, and the students' attendance record 314 for a specific week 304 and 306. This information is processed through the manage student information screen 500, as shown in FIG. 5. In the manage/take class attendance screen 300, a user need only input whether the student was absent or not 312, and optionally the reason for the absence. Once this information is inputted, a user can update the on-line attendance information by clicking the update button 316, or exit the screen by clicking the exit button 318.

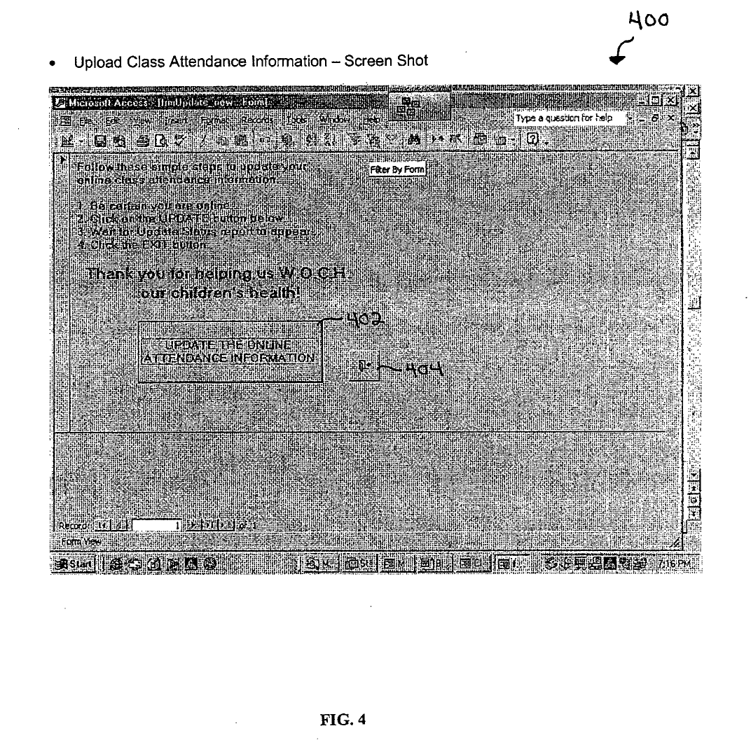

If a user chooses to update the attendance information, they are transferred to the upload class attendance screen 400, as shown in FIG. 4. A user then follows the simple instructions. First, a user must be on-line, then they click the update button 402 and wait for the update status report to appear, and then they click the exit button 404 to exit the screen 400.

A user can also manage student information by entering the manage student information screen 500, as shown in FIG. 5. A user then selects a specific method of managing student data by clicking on the specific category. For example, a user can choose to edit class information 502, add a new student 504, edit student information 506, enter/view grade levels 508, edit teacher information 510, select the Start week for the school term 512, or return to the main menu 514.

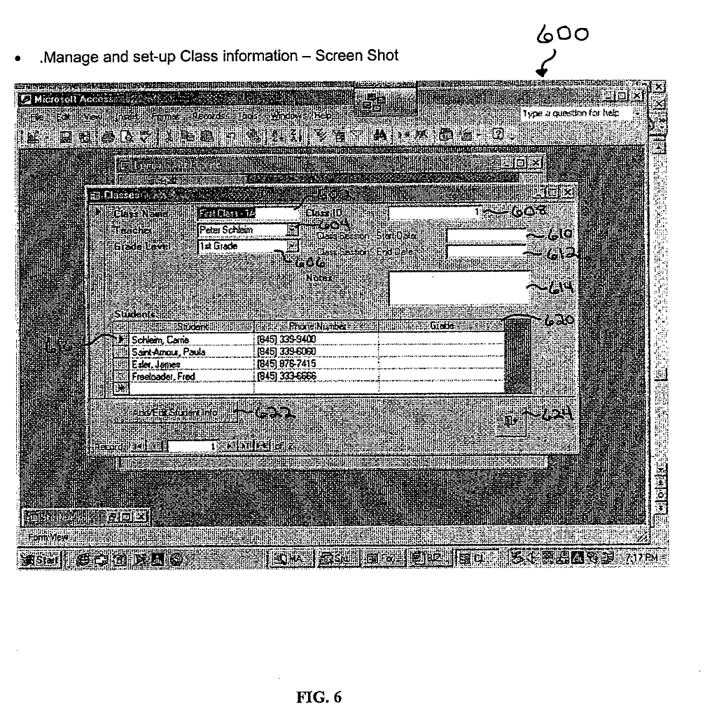

If a user chooses to edit class information 502, they are transferred to the manage and set-up class information screen 600, as shown in FIG. 6. A user then enters the class name 602, teacher 604, grade level 606, and class ID 608. Then, the class session start date 610 and end date 612 is inputted, and any notes 614 about the class and/or students. Finally, the students' names 616 are input, their phone numbers 618, and grade 620. Once this information is entered, a user clicks on the add/edit student information button 622 to save the changes, or exit the screen by clicking on the exit button 624.

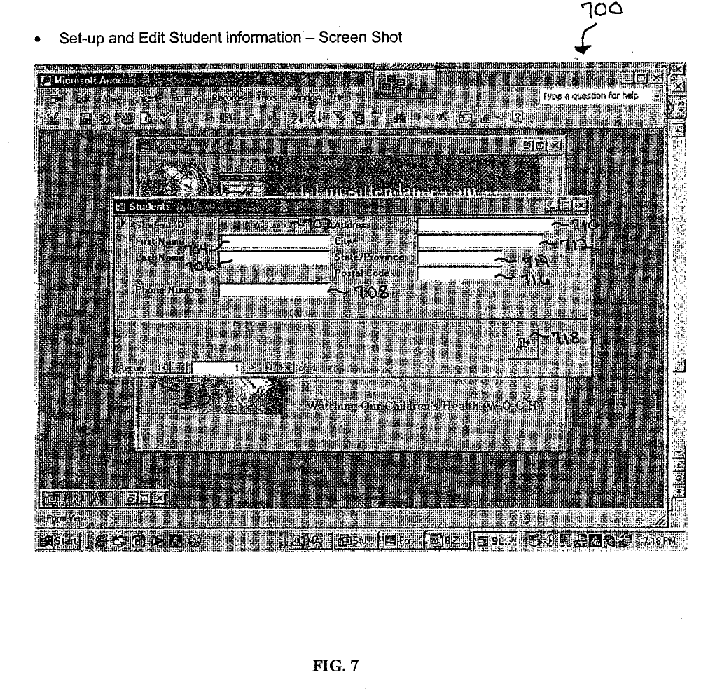

If a user chooses to add/edit student information 622, they are transferred to the set-up and edit student information screen 700, as shown in FIG. 7. A user then enters the student's ID number 702, first name 704, last name 706, phone number 708, street address 710, city 712, state/providence 714, and postal code 716. Once the information is entered and saved, the user can exit the screen by clicking the exit button 718.

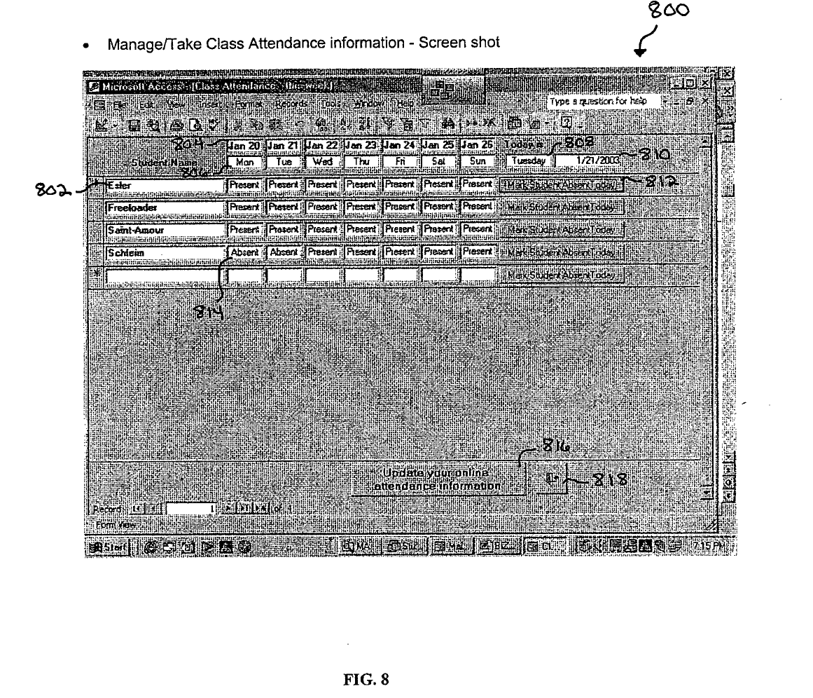

Another process methodology for the collection of attendance data, is the use of active devices, such as Palm type hand-held devices 108. Active, Palm type hand-held devices 108 allow a user to enter the attendance log directly into the hand-held device and then upload the information to a proprietary desk-top application 106. For example, a user enters the attendance log via the manage/take class attendance screen 800, as shown in FIG. 8. The attendance screen 800 displays the selected student's name 802, the date 810, day of the week 808, and the students' attendance record 814 for a specific week 804 and 806. This information is processed through the manage student information screen 500, as shown in FIG. 5. In the manage/take class attendance screen 800, a user need only input whether the student was absent or not 812. Once this information is inputted, a user can update the on-line attendance information by clicking the update button 816, or exit the screen by clicking the exit button 818.

Another process methodology for the collection of attendance data, is the use of a combination of active/passive RFID devices that utilize smart RFID (Radio Frequency Identification) technologies 110. Devices, such as an ID bracelet, badge, or watch embedded with an RFID tag, worn by the student 110, puts out an RFID signal which automatically reports the child's presence to a networked identification data capture reader (a proximity RFID reader) 111. The reader 111 is linked online to a web server 120 to upload the data.

Another process methodology for the collection of attendance data, is the method of manually inputting daily class attendance 112. The paper-based method 112 allows a user to print out a daily class attendance log, and manually take attendance on the paper log. The paper log is collected and then either entered manually 114, directly into a desk-top application 106, or entered manually 116, on-line through a web server 120.

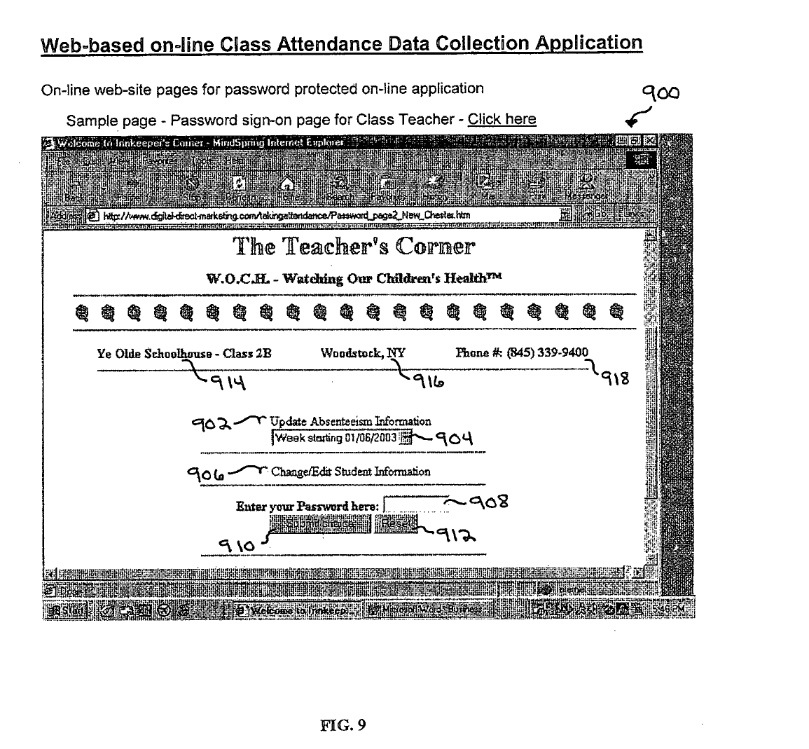

Finally, the last process methodology for the collection of attendance data, is the use of an on-line web based application 118. The on-line web based application 118 allows a user to access password protected on-line applications and enter the attendance information directly on-line through a web server 120. For example, a user logs into the password sign-on screen 900, as shown in FIG. 9. Here, a user first enters their password 908 and logs in. The sign-on screen 900 then displays the school and class 914, location 916 and phone number 918. A user can then choose to update absenteeism information 902, for a specific week 904 or change/edit student information 906. Once a user makes a choice, they click on the submit choice button 910 to enter their choice or the reset button 912 to reset the screen.

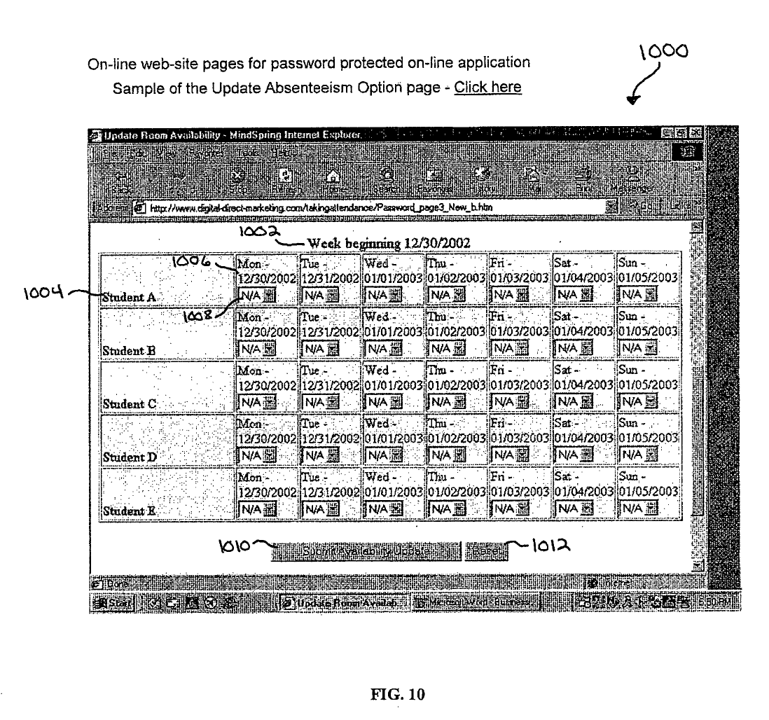

If a user chooses to update absenteeism information 902, they are transferred to the update absenteeism screen 1000, as shown in FIG. 10. The absenteeism information is displayed for a specific week 1002. The students names are listed in the far left column 1004, and each specific day of the week 1006 is displayed across the table. The absenteeism information 1008 can then be entered for each student, for each day of the specified week. Once the updates are made, a user clicks on the submit availability update button 1010 to save the information or clicks on the reset button 1012 to reset the screen.

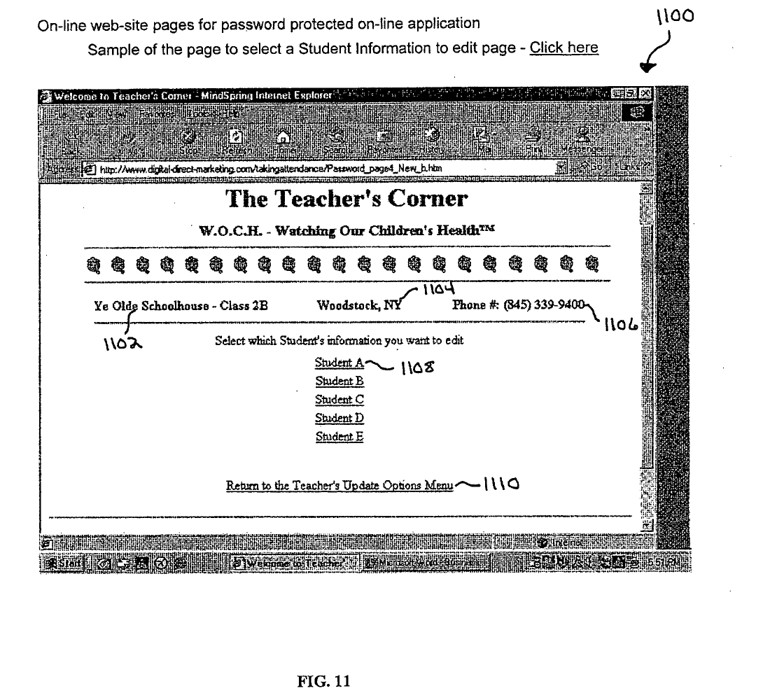

If a user chooses to change/edit student information 906, they are transferred to the select a student information screen 1100, as shown in FIG. 11. This screen again displays the name of the school and class 1102, the school's location 1104 and phone number 1106. A user then clicks on a specific student's information 1108 to edit that student's information or clicks on the Return to Update Menu button 1110 to return to the main menu.

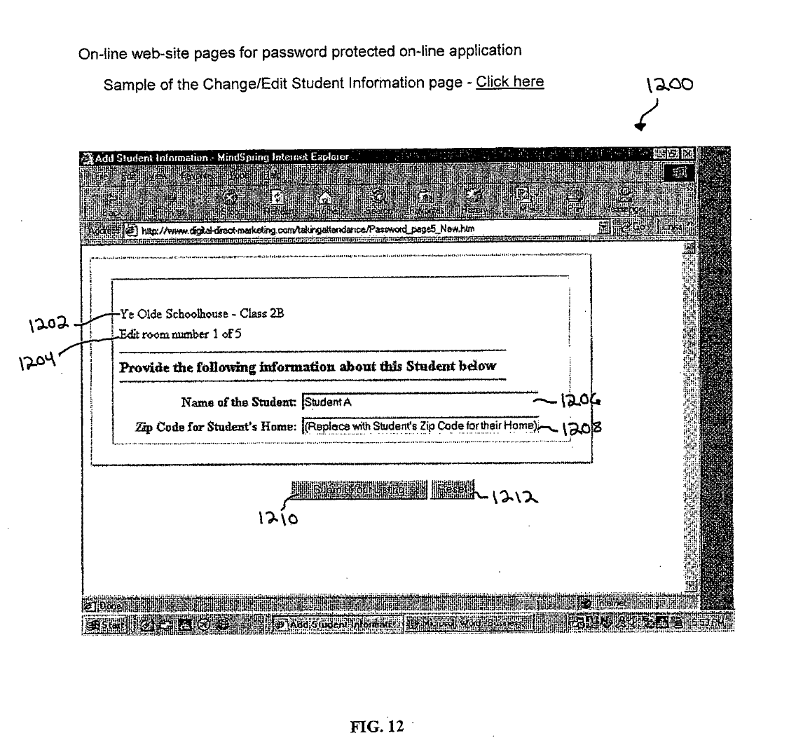

If a user chooses a specific student's information 1108 to edit, they are transferred to the change/edit student information screen 1200, as shown in FIG. 12. This screen also displays the name of the school and class 1202 and the number of edits performed 1204. The name of the specific student is then entered 1206, along with the zip code for the student's home 1208. Once this information is listed, a user then clicks on the submit your listing button 1210 to save the information, or clicks on the reset button 1212 to reset the screen.

Once the attendance information is entered into the system 100, via any of the above methods, the on-line web-site/server 120 then transfers the attendance information to another web-site for storage 124. The stored data can then be transferred to the on-line aggregation software 126, where the data is analyzed to track changes and identify data anomalies and/or spikes in absenteeism. These spikes in absenteeism would serve as possible predictors of any emerging public health risk. Thus, with this attendance information, an informed decision 128 can be made based on the reported public-health trends.

Typically, school attendance is routinely taken for more than ninety two million children in the nation's school systems. Users of the early alert and response system 100 need only to input this data into the attendance tracking software system via the methods discussed above. This system is designed to be intuitive and easy to use by a user having even minimal amounts of computer experience. Additionally, the only minimal requirement required by the system 100, is access to the Internet. All other parts of the systems can be deployed independent of any other requirements to deploy additional computer hardware or software.

Overall, the system 100 would aggregate attendance records and monitor changes in absence levels for children in elementary schools. The system would track 100% of this target population by aggregating the attendance records to track absences of greater than one day. The proposed system 100 uses geo-coded zip code data and other dynamic regional data analyses to perform cluster analysis, track changes, and identify data anomalies, such as spikes in absenteeism. These spikes in absenteeism would serve as possible predictors of any emerging public health risk. While large variations in absences exist along social class, age, gender and ethnicity lines, attendance data gathered by this system 100 can be modeled to provide an effective early warning tool to identify an emerging public-health problem.

Additionally, the proposed system 100 does not impose any new data entry requirements to a user's (teacher's) workload. The system 100 proposes to time-shift the reporting of the attendance data to make it available in real-time. Further, the tracking of attendance records also has internal uses within the schools 122. For example, the attendance information could be used to track truancy levels within the school, track fire drills and other safety programs, or used for district reporting.

Initially, the model will only track, analyze and model a subset of the public school systems and not monitor private schools. The subset of the public school systems includes kindergarten through 3rd grade or 14,426,000 children or an estimated 577,040 classes (assuming an average of 25 children per class). Spikes in absenteeism will then be matched to a normative base line.

The proposed system 100 does not utilize any sampling approaches, thus there is no statistical sampling error. The system 100 can track 100% of this target population. Additionally, initial data gathering is not subject to missed diagnosis error or non-reported problems. Tracking this target population minimizes the number of non-health-factor variables (truancy, missed home class but in school, etc.). Therefore, minimizing non-significant variables that might mask emerging health problems, maximizes analysis significance.

Alternative systems that rely on doctors or hospitals may miss many initial problems due to a) their not even being recorded or b) as a result of a significant time delay between the onset of an illness and going to see a doctor. Most adults self-medicate illness before seeing a physician (particularly true for men). Early alert and response systems that rely on doctors diagnosing a health problem are dependent on correct and timely diagnosis.

In addition the data is not skewed as a result of differences between support (participation) vs. non-support (non-participation) population demographics. 100% of the target population is being polled and tracked. This is one of the highest at-risk segments of the U.S. population. The model is not relying on self-reported information. The data is not subject to self-censoring or lying, because third party professionals (e.g., teachers) are collecting and submitting the data; thus, the inherent processes already exist.

Further, requiring attendance records would not result in the promulgation of any new legislation. Attendance is currently taken in every classroom in the U.S. It is not believed that the proposed aggregating of absence data would raise any privacy issues or require either legislative or public commentary. Privacy would be maintained, as we do not propose that any specific information (other than absence data) about the child would be shared because it would not be passed up in the aggregation process. Full anonymity—no personal information about the child is being transmitted and aggregated.

Further according to an additional embodiment of the present invention, the system 100 is adapted to communicate with parental figures (e.g., parents, guardians, etc.) of associated students. Once the teacher takes attendance and inputs the attendance information into the system 100, the system 100 is adapted to display a list of students who are absent. Upon receiving the list of absent students, the system 100 is configured to either automatically notify a parental figure associated with each absent student of the fact of the student's absence or to enable the teacher to cause such a notification to be issued. The notification is through any suitable means, such as email, mail, telephone, cellular phone, pager, personal digital assistant (“PDA”), and the like.

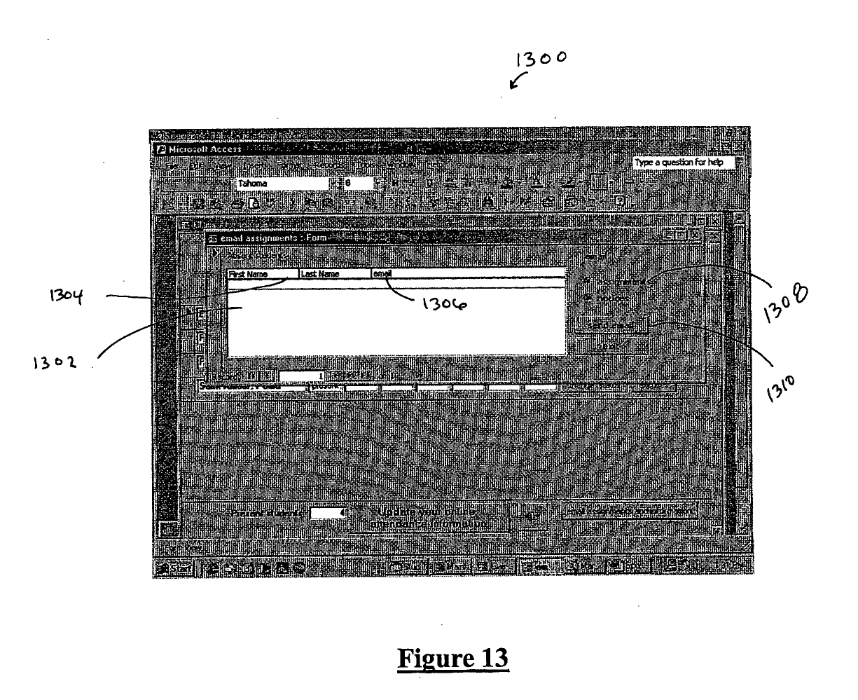

With reference to FIG. 13, the system is further adapted to communicate homework assignment information to the parental figures of absent students. FIG. 13 illustrates an example email screen 1300 that enables the teacher to email homework assignment information to the parental figures. The email screen 1300 includes an automatically generated list 1302 of absent students. Although the example email screen 1300 of FIG. 13 does not include an illustrated list of students, it is to be understood that such a list would appear in the list 1302 portion of the screen 1300. The generated list 1302 includes the name 1304 of each absent student and an email address 1306 of a parental figure associated with each absent student. To email homework information, the teacher selects one of the student names from the list 1302, selects the assignments button 1308, and selects the sent email button 1310. Upon selecting the email button 1310, the teacher inputs the homework information. For example, a drive browsing screen suitably appears that enables the teacher to identify a file having the homework information and attach the file to the email sent to the parental figure.

Additionally disclosed according to another example embodiment of the present invention is an electronic school bus routing system. Most parental figures now work outside the home and the need to manage after school child-care is a daily requirement. Over the past few decades, parental figures of school-aged children have been working longer hours and spending less time at home. Not only are their days at work longer, but nearly one in five employed parental figures faces the pressure of managing a single-parent household. This dramatic shift has left more than half of all families with children under the age of 13 requiring some form of non-parental after school child-care. After school child care includes such options as child care centers provided in nonresidential facilities, usually for 13 or more children, family child care providers provided in a private residence other than the child's home, in-home care providers provided within the child's home, by a person other than a parental figure or relative, relative care provided by an individual related to the child, self-care or latch-key children who are home alone after school each week during afternoon hours, etc. Parental figures of school-aged children frequently need to be able to change or modify after-school child-care arrangements. Accordingly, the bus routing system enables parental figures to monitor a bus route assigned to their child and select a different route, if necessary.

The bus routing system is suitably provided as web-based Internet application accessible through a plurality of portals, such as from a home computer system, a work computer system, a personal digital assistant, a cellular phone, etc. According to the system, a parental figure first accesses the web-based application and inputs an identification of the parental figure's student, such as a name, a social security number, etc. After inputting the identification, the parental figure will be required to input a password to authenticate the parental figure's use of the application. After being authenticated, the application displays a bus route assigned to the subject student. The application additionally displays a plurality of alternate bus routes available to be used for the student. Accordingly, as necessary, the parental figure selects an alternate bus route to be assigned to the student for a specified period (e.g., a day, a range of days, a week, a month, etc.). Upon selecting the alternate bus route, the application automatically assigns the new route to the subject student and causes an associated bus system to operate accordingly.

The bus routing system suitably also includes an additional level of security. For example, upon selecting an alternate bus route, the application transmits an email confirmation to the parental figure of the subject student. The email confirmation suitably includes a unique authorization code. At some point prior to the parental figure's use of the bus routing system, the system has been programmed to recognize an email address for the parental figure. Accordingly, the email will be transmitted to only the parental figure of the student that is the subject of current bus route altering. Once the parental figure receives the email, it will return to the application and input the authorization code. If the input authorization code matches the transmitted authorization code, the system will assign the new bus route to the subject student. If the input authorization code does not so match, it will not effect the bus route change. Accordingly, the system is adapted to provide both access security (the input password must match a password stored with the application) and identity confirmation (through the use of the email authorization code transmission).

Although the preferred embodiment has been described in detail, it should be understood that various changes, substitutions, and alterations can be made therein without departing from the spirit and scope of the invention. It will be appreciated that various changes in the details, materials and arrangements of parts, which have been herein described and illustrated in order to explain the nature of the invention, may be made by those skilled in the area within the principle and scope of the invention.

What is claimed is:

1. An electronic system for identifying a public health risk comprising:
attendance input means adapted for periodically receiving data representative of attendance information for at least one selected student;
associating means adapted for associating the input attendance information with demographic information of the at least one selected student to form associated attendance information;
analyzing means adapted for analyzing the associated attendance information against data representative of selected criteria to identify a public health risk; and
means for outputting data representative of an identified public heath risk.

2. The system of claim 1, wherein the demographic information of the at least one student includes at least one of a home address, a postal code corresponding to the home address, emergency contact information, an identification of at least one legal guardian, and an email address of the at least one legal guardian.

3. The system of claim 2 further comprising transmitting means adapted for transmitting the associated attendance information to a remote data processing device, and wherein the analyzing means is associated with the remote data processing device.

4. The system of claim 3, wherein the remote data processing device comprises sorting means adapted for sorting the received attendance information into one of a plurality of categories, each corresponding to a pre-specified postal code.

5. The system of claim 4, wherein the analyzing means identifies a public health risk by analyzing trends in attendance data relative to each postal code category.

6. The system of claim 1, further comprising attendance input means includes at least one of a local desktop computer, a handheld device, an Internet-accessible web page, an radio frequency identification device and a machine readable indicia.

7. The system of claim 4 further comprising email notification means adapted for automatically creating and transmitting to the parental figure of the at least one student an email message comprising attendance information of the at least one student.

8. The system of claim 7, wherein the email message further comprises homework information for the at least one student.

9. A method for identifying a public health risk comprising the steps of:
periodically receiving input data representative of attendance information for at least one selected student;
associating the input attendance information with demographic information of the at least one selected student to form associated attendance information;
analyzing the associated attendance information against data representative of selected criteria to identify a public health risk; and
outputting data representative of an identified public heath risk.

10. The method of claim 9, wherein the demographic information includes at least one of a home address of the student, a postal code corresponding to the home address of the student, emergency contact information for the student, an identification of at least one parental figure of the student, and an email address of the at least one legal guardian.

11. The method of claim 10 further comprising the step of transmitting the associated attendance information to a remote data processing device, and wherein an analyzing means associated with the remote data processing device performs the step of analyzing the associated attendance information.

12. The method of claim 11 further comprising the step of sorting the received attendance information into one of a plurality of categories, each corresponding to a pre-specified postal code.

13. The method of claim 12 further comprising the step of identifying a public health risk by analyzing trends in attendance data relative to each postal code category.

14. The method of claim 9, wherein the step of receiving user input representative of attendance information is performed with at least one of a local desktop computer, a handheld device, an Internet-accessible web page, and an article of paper having machine readable indicia.

15. The method of claim 12 further comprising the step of automatically creating and transmitting to the legal guardian an electronic message comprising attendance event information of the at least one student.

16. The method of claim 15, wherein the email message further comprises homework information for the at least one student.

17. An electronic school bus routing system comprising:
assigned bus route displaying means adapted for displaying assigned bus route information for at least one selected student;
alternate bus route displaying means adapted for displaying at least one alternate bus route information for the at least one selected student; and
selection means adapted for receiving user input representative of a selection of an alternate bus route for the at least one selected student.

18. The electronic school bus routing system of claim 17 further comprising security means adapted for controlling access to the bus route displaying means, wherein the security means is operably only upon input of valid security information.

19. The electronic school bus routing system of claim 17 further comprising authorization code transmitting means adapted for transmitting to the user an authorization code upon the selection of an alternate bus route.

20. The electronic school bus routing system of claim 19 further comprising assigning means adapted for assigning the selected alternate bus route to the student, wherein the assigning means is operable only upon input of the authorization code.
